(19) United States
(12) Patent Application Publication
(10) Pub. No.: US 2008/0129295 A1
(43) Pub. Date: Jun. 5, 2008

(54) Seamless Enclosures for Mr Rf Coils

(75) Inventor: John T. Carlton, Madison, OH (US)

Correspondence Address: PHILIPS INTELLECTUAL PROPERTY & STANDARDS, 595 MINER ROAD, CLEVELAND, OH, 44143, US

(73) Assignee: KONINKLIJKE PHILIPS ELECTRONICS N.V., Eindhoven (NL)

(21) Appl. No.: 11/817,969

(22) PCT Filed: Mar. 3, 2006
(86) PCT No.: PCT/IB06/50681

§ 371 Date: Sep. 7, 2007

Related U.S. Application Data
(60) Provisional application No. 60/660,299, filed on Mar. 10, 2005.

(51) Int. Cl. G01R 33/34; H05K 5/00; H01R 43/033; B21F 15/00

(52) U.S. Cl. 324/318; 361/679; 29/856; 156/51

(57) ABSTRACT

A reusable coil assembly (36) for use within a contaminated environment includes a seamless outer envelope (38). An RF coil element (70) and an electronic circuit (88) are encased within the seamless outer envelope (38). The RF coil element (70) is connected to the electronic circuit (88). The outer envelope (38) is integrally constructed from a thermoplastic material using Fused Deposition Modeling process.

The following relates to the magnetic resonance arts. It finds particular application in conjunction with local coils for medical magnetic resonance imaging systems and will be described with particular reference thereto. It is to be appreciated, however, that the present invention may also find application in conjunction with other types of magnetic resonance systems, magnetic resonance spectroscopy systems, and the like.

In magnetic resonance imaging, a substantially uniform main magnetic field is generated within an examination region. The main magnetic field polarizes the nuclear spin system of a subject being imaged within the examination region. Magnetic resonance is excited in dipoles which align with the main magnetic field by transmitting radio frequency excitation signals into the examination region. Specifically, radio frequency pulses transmitted via a radio frequency coil assembly tip the dipoles out of alignment with the main magnetic field and cause a macroscopic magnetic moment vector to precess around an axis parallel to the main magnetic field. The precessing magnetic moment, in turn, generates a corresponding radio frequency magnetic signal as it relaxes and returns to its former state of alignment with the main magnetic field. The radio frequency magnetic resonance signal is received by the radio frequency coil assembly, and from the received signals, an image representation is reconstructed for display on a human viewable display.

In certain medical MRI applications, it is advantageous to perform imaging scans over a limited field of view and depth of penetration of specific regions of the patient being examined. In some applications, the organ or region of interest is internal and proximal to a body cavity. Such regions may include the anus, the prostate, the cervix, and other regions associated with internal cavities of a patient. In other applications, the coils are held against external portions of the patient.

Typically, RF coils that are used in interventional applications are constructed of medical grade plastic. Because these coils come in contact with mucus membranes, blood barriers or other bodily fluids, high level disinfection or sterilization are desirable. Such coils are subject to strict requirements for surface disinfection and cleaning after each use. The coils are often constructed of a coil and electronics encased in a plastic housing compound of multiple pieces of plastic, and thus have seams where the pieces meet. Fine crevices, such as seams between plastic parts, trap and shelter microbes making cleaning and disinfection a difficult task. Microscopic organisms can become lodged in the crevices where liquid sterilants cannot assuredly eliminate the bacteria. Currently, the seams are filled in or the entire assembly is coated with a USP Class VI epoxy which meets the biotoxicity requirements that the coil be cleanable and disinfectable between patients. However, such process is expensive.

The following contemplates improved apparatuses and methods that overcome the aforementioned limitations and others.

According to one aspect, a reusable coil assembly for use within a contaminated environment is disclosed. The coil assembly includes a seamless outer envelope, an RF coil element which is rigidly internally positioned within the outer envelope, and an electronic circuit which is encased within the seamless outer envelope, the electronic circuit being connected to the RF coil element.

According to another aspect, a method of manufacturing a disinfectable RF coil assembly is disclosed. An RF coil element is connected to an electronic circuit. The RF coil and the electronic circuit are encased in a seamless outer envelope.

One advantage resides in eliminating seams or crevices that are difficult to clean and disinfect.

Another advantage resides in an improved reusability of easily contaminated coil assemblies.

Another advantage resides in simplicity of manufacture.

Numerous additional advantages and benefits will become apparent to those of ordinary skill in the art upon reading the following detailed description.

The invention may take form in various components and arrangements of components, and in various process operations and arrangements of process operations. The drawings are only for the purpose of illustrating preferred embodiments and are not to be construed as limiting the invention.

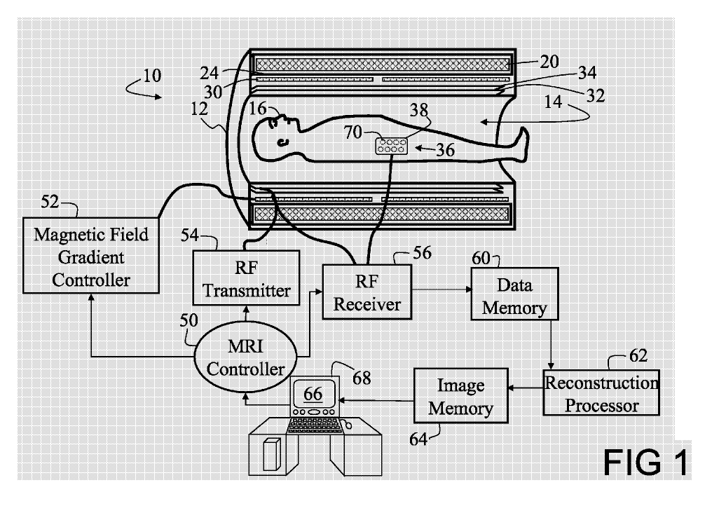

FIG. 1 diagrammatically shows a magnetic resonance imaging system employing a local radio frequency coil;

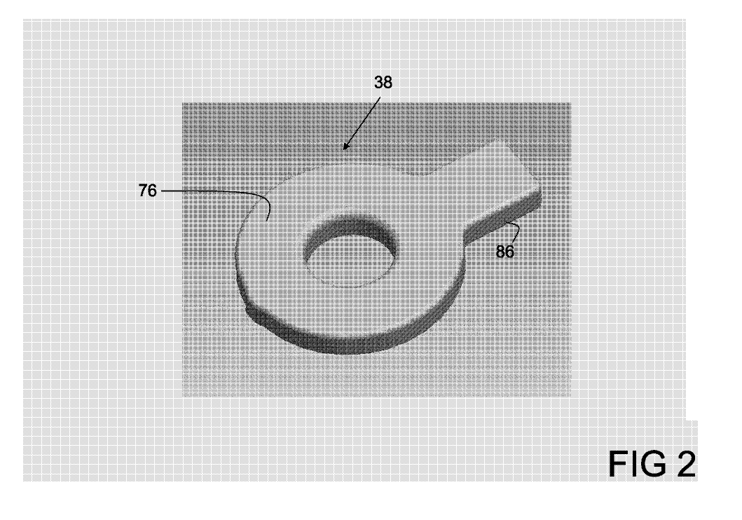

FIG. 2 shows a picture of a seamless MR coil enclosure;

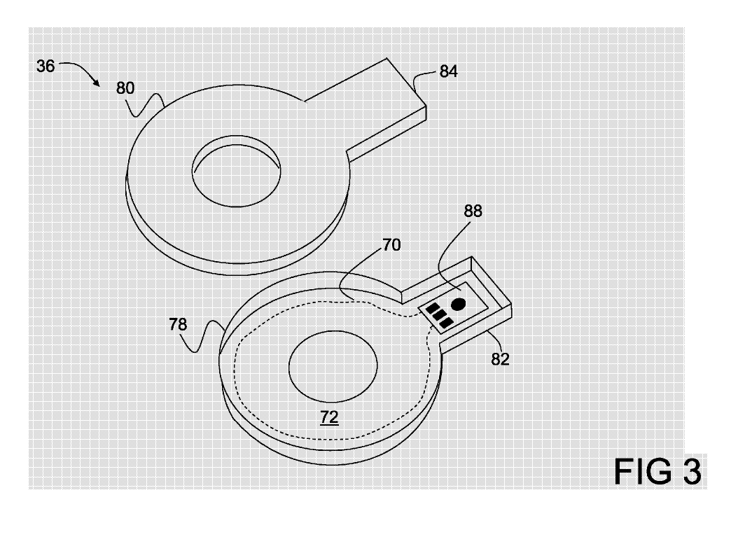

FIG. 3 diagrammatically shows an expanded view of a coil assembly and associated electronics;

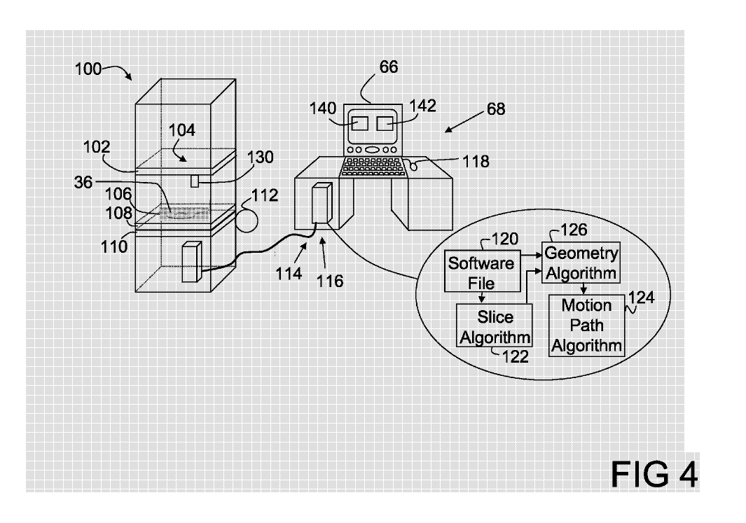

FIG. 4 diagrammatically shows a portion of an extrusion process used to manufacture a seamless enclosure of FIG. 2;

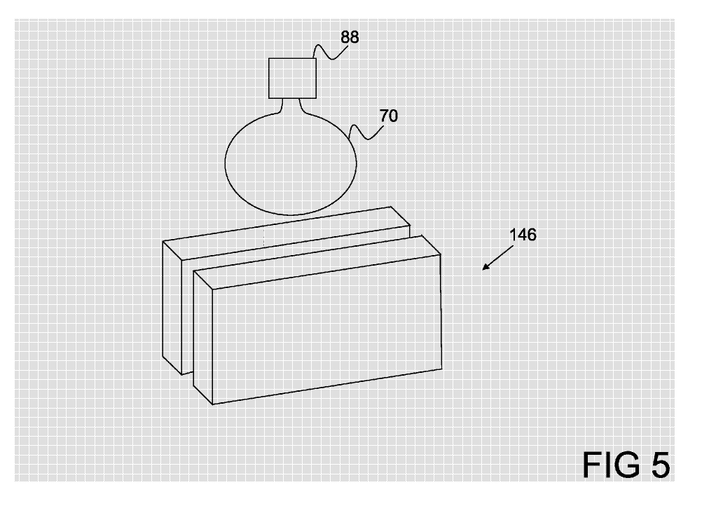

FIG. 5 diagrammatically shows a process for molding an MR coil;

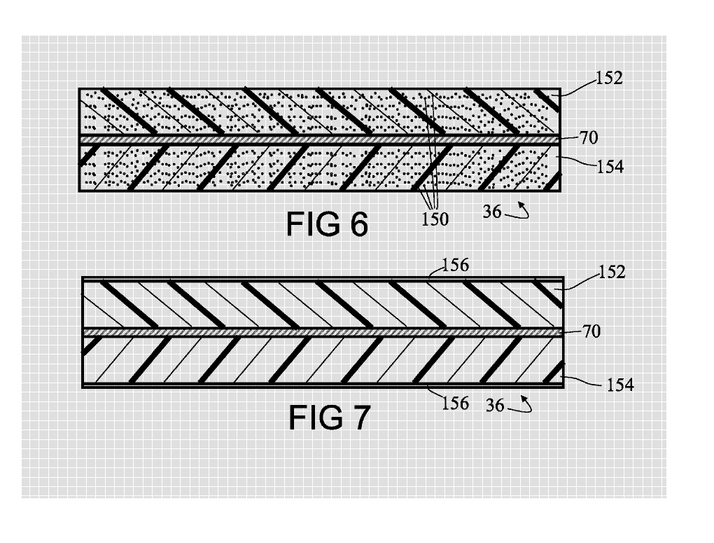

FIG. 6 diagrammatically shows an expanded vertical view of a section of the coil assembly with dispersed anti-microbial agent; and

FIG. 7 diagrammatically shows an expanded vertical view of a section of the coil assembly with a coating which includes an anti-microbial agent.

With reference to FIG. 1, a magnetic resonance imaging scanner 10 includes a housing 12 defining an examination region 14 in which a patient or other imaging subject 16 is disposed. A main magnet 20 disposed in the housing 12 generates a substantially spatially and temporally constant main magnetic field in the examination region 14. Typically, the main magnet 20 is a superconducting magnet surrounded by cryoshrouding 24; however, a resistive main magnet can also be used. Magnetic field gradient coils 30 are arranged in or on the housing 12 to superimpose selected magnetic field gradients on the main magnetic field within the examination region 14. Typically, the magnetic field gradient coils 30 include a plurality of coils for generating magnetic field gradients in a selected direction and at a selected gradient strength within the examination region 14. For example, the gradient coils 30 may include x-, y-, and z-gradient coils that cooperatively produce the selected magnetic field gradient in any selected direction.

A whole-body radio frequency coil 32, such as a stripline coil disposed on an insulating dielectric former with a with a surrounding RF shield 34, a birdcage coil with rigid conductive rungs and rings, or so forth, is arranged in or on the housing 12 to inject radio frequency excitation pulses into the examination region 14 and to detect generated magnetic resonance signals. For generating images of limited regions of the subject 16, one or more local RF coils are commonly placed contiguous to the selected region. In one embodiment, the local coils are interventional or otherwise easily contaminated coils which can be either introduced into the patient's body, such as endocavitary coil prostate coil, biopsy breast coil, catheter coil and the like, or placed adjacent the patient's body such as an illustrated coil assembly 36. The coil assembly 36 includes a seamless enclosure or case 38 in which an active coil element and an appropriate drive electronics are encased as will be discussed in a greater detail below.

A magnetic resonance imaging (MRI) controller 50 executes a selected magnetic resonance imaging sequence. The controller 50 operates magnetic field gradient controllers 52 coupled to the gradient coils 30 to superimpose selected magnetic field gradients on the main magnetic field in the examination region 14, and operates a radio frequency transmitter 54 coupled to the radio frequency coil 32 as shown, or to the local coil 36, surface coil, coils array, or so forth, to inject selected radio frequency excitation pulses at about the magnetic resonance frequency into the examination region 14. For two-dimensional imaging, the radio frequency excitation also includes a concurrent slice-selective magnetic field gradient imposed by the gradient system 30, 52.

The radio frequency excitation pulses excite magnetic resonance signals in the imaging subject 16 that are spatially radially encoded by applying a magnetic field gradient in a selected direction and with a selected gradient strength in accordance with the selected short echo time magnetic resonance imaging sequence. The imaging controller 50 operates a radio frequency receiver 56 connected with the radio frequency coils 36 (or 32) in accordance with the selected magnetic resonance imaging sequence to receive the radial readout magnetic resonance signals, and the received radial readout data are stored in a data memory 60.

A reconstruction processor 62 reconstructs the data into a 3D image representation by applying a fast Fourier transform or other appropriate reconstruction algorithms. The reconstructed image is stored in an image memory 64, and can be displayed on a user interface 66 of a workstation 68, transmitted over a local area network or the Internet, printed by a printer, or otherwise utilized. In the illustrated embodiment, the user interface 66 also enables a radiologist or other user to interface with the imaging controller 50. In other embodiments, separate user interfaces are provided for operating the scanner 10 and for displaying or otherwise manipulating the reconstructed images.

With reference to FIGS. 2-3, the coil assembly 36 includes the seamless enclosure 38, in which an active RF coil element 70 is rigidly secured. More specifically, the coil element 70 is looped and securely fastened in a hollow cavity 72 of a ring section 76, more exactly, in a lower ring half 78. The lower ring half section 78 is connected to an associated lower half shaft portion 82 of a shaft 86, which houses appropriate electronics 88 such as a printed circuit board, which includes a tuning and matching circuitry. After the electronics are installed, formation of the lower halves 78, 82 is continued forming associated upper halves 80, 84 to form the integral case 38. The case is preferably constructed with a USP Class VI plastic which meets the biotoxicity requirements of interventional products. An RF cable (not shown) connects the output of the tuning and matching circuit to the MRI system preamplifier. Preferably, the cable is constructed from a non-magnetic version of a standard RG174 cable. Over the outer cable insulation, a non-toxic PVC outer jacket is preferably molded. The PVC jacket provides an appropriate non-toxic contact with the patient and also provides an electrical field insulating distance between the patient and the outer electrical shield of the cable thereby preventing the risk of RF burn.

With reference to FIG. 4, an extrusion machine 100 manufactures the seamless enclosure 38 directly from CAD files by using Fused Deposition Modeling (FDM). Unlike other materials, the properties of the FDM materials do not change with time or environmental exposure. More specifically, a cartridge 102 carrying an appropriate thermoplastic material 104 is inserted into the machine 100. One example of such material is a USP Class VI polycarbonate which is bio-compatible material for a use with the interventional instruments. Other thermoplastic materials which can withstand greater forces and loads are also contemplated, such as polyphenylsulfone, elastomer, wax and the like.

Typically, the material is a cordlike material that is wound on a spool. A plastic base 106 is inserted into a holding tray 108 which is positioned into a platform 110. The platform 110 includes an associated drive 112 such as motors and driving mechanisms that facilitate precise motion of the platform 110 forward, rearward, left, right, up and down. A user creates a software file 120, which contains the appropriate CAD drawing information for the associated enclosure 38 by using the workstation 68 or any other appropriate computer. The workstation 68 includes a hardware 114, software 116, and input means 118, such as a keyboard and a mouse, to facilitate control of the extrusion machine 100. A slice algorithm 122 slices the enclosure 38 into a multiplicity of thin flat layers. Preferably, each layer is about 0.05 mm thick. A geometry algorithm 126 calculates the enclosure 38 geometry at each layer. A motion path generating algorithm 128 calculates the paths, which an extrusion head 130 makes while extruding. Typically, the geometry of the enclosure 38 is split into a multiplicity of small cross-sectioned ribbon, preferably with a cross-section less than 0.01 mm², e.g., a 0.05×0.05 mm square cross-section, to form each layer. The extrusion head 130 stays in place while the platform 110 is moved forward, rearward, left and/or right while the extrusion head 130 is extruding the small cross-sectioned ribbon to fill in the designated geometry. Alternately, the extrusion head 130 can move in the horizontal plane and the platform 110 only index downward. The material is raised to an associated softening or melting pressure and temperature such that it hardens substantially instantly upon application. Preferably, the chamber, in which the material cartridge is enclosed, is kept at a constant temperature. When the current layer is completed, the platform 110 is moved down such that the next layer can be extruded. In this manner, the geometry of the enclosure 38 is built up in successive layers of small ribbon.

After the extrusion machine 100 builds the first half or lower sections 78, 82 of the enclosure 38, the extrusion machine 100 is stopped by a pause means 140 such as a user activated switch “Pause.” The platform 110 with the base 106 is moved out of the extrusion machine 100. The coil element 70 and the electronics 88 are inserted into the corresponding lower half sections 78, 82, after which the platform 110 is moved once more into the extrusion machine 100. An extrusion resuming means 142 such as a user activated switch “Resume” activates a continuation of the extrusion process to continue building on the lower sections 78, 82 integrally forming the associated upper half sections 80, 84 of the enclosure 38. The platform 110 with the completed coil assembly 36 is moved from the extrusion machine 110. The plastic base 106, on which the completed enclosure 38 with the enclosed coil element 70 and electronics 86 is disposed, is removed from the tray 108. The coil assembly 36 is removed from the base 106, cleaned, sanded to a smooth finish, polished, and the like.

In the described manner, using the multilayer extrusion process, the manufacturing of different geometry seamless enclosures can be performed.

With reference to FIGS. 5-6, the coil 70 and the electronics 88 are suspended in a mold 146, e.g., reusable silicone mold. A liquid urethane molding compound which meets the USP Class VI requirements is poured into the mold encasing the coil and electronics. The use of the liquid molding compounds at low injection pressures decreases the chance of damaging the coil assembly during the manufacturing process.

Optionally, the coil and the electronics can be mounted on a plastic or dielectric former or mounted in a seamed housing, which is placed in the mold for encapsulation in the liquid urethane.

With reference to FIG. 6, in one embodiment, to further reduce the likelihood of spreading infectious microbes, an anti-microbial agent 150 is preferably incorporated into outer cover layers 152, 154 of the enclosure 38. In FIG. 7, the anti-microbial agent is diagrammatically represented by discrete dots; however, the anti-microbial agent is preferably a substance that is incorporated into the plastic material used in extruding the enclosure 38 and is incorporated substantially uniformly throughout the outer layers 152, 154.

With reference to FIG. 7, an integral anti-microbial coating 156 is applied to the outer surfaces of the outer cover layers 152, 154, respectively.

The coil assembly 36 including the anti-microbial agent advantageously reduces the likelihood of spreading infectious pathogens between patients. Moreover, an anti-microbial agent can be incorporated into other portions of the magnetic resonance imaging system that are contacted by the imaging subject 16 or by a radiologist, technician, or other operator. For example, the keyboard 118 or other operator control, the gantry or housing 12, the patient support, or the like can incorporate an anti-microbial agent. Similarly, pads used to position or comfort the imaging subject 16 can incorporate an anti-microbial agent. Incorporating an anti-microbial agent into surfaces contacted by the imaging subject 16 or the radiologist helps prevent the spread of infectious pathogens between patients or between a patient and the radiologist.

The invention has been described with reference to the preferred embodiments. Obviously, modifications and alterations will occur to others upon reading and understanding the preceding detailed description. It is intended that the invention be construed as including all such modifications and alterations insofar as they come within the scope of the appended claims or the equivalents thereof.

1. A reusable coil assembly for use within a contaminated environment, comprising:
a seamless outer envelope;
an RF coil elements, which is rigidly internally positioned within the outer envelope; and
an electronic circuit, which is encased within the seamless outer envelope, the electronic circuit being connected to the RF coil element.

2. The coil assembly as set forth in claim 1, wherein the outer envelope includes a multiplicity of molded layers.

3. The coil assembly as set forth in claim 1, wherein the outer envelope is integrally constructed using Fused Deposition Modeling.

4. The coil assembly as set forth in claim E, wherein the outer envelope is constructed from a thermoplastic material which meets USP Class VI biotoxicity requirements.

5. The coil assembly as set forth in claim 4, wherein the outer envelope is constructed from a polycarbonate material.

6. The coil assembly as set forth in claim 1, wherein the outer envelope includes a molded seamless outer surface constructed of a plastic.

7. The coil assembly as set forth in claim 6, wherein the outer envelope is molded from a liquid urethane molding compound.

8. The coil assembly as set forth in claim 6, wherein the RF coil and electronic circuit are encased by the molded plastic.

9. A magnetic resonance imaging system including the coil assembly of claim 1.

10. A method of manufacturing a disinfectable RU coil assembly comprising:
connecting an RF coil element with an electronic circuit; and
encasing the RF coil and the electronic circuit in a seamless outer envelope.

11. The method as set forth in claim 10, wherein the encasing step includes:
extruding ribbons of thermoplastic material in a prespecified geometry to form a first section of the outer envelope;
stopping the extrusion press;
securing the RU coil element and the electronic circuit within the first section of the outer envelope; and
continuing extruding the thermoplastic ribbons to seamlessly continue building a second portion of the outer envelope such that there is no seam between the first and second sections of the outer envelope.

12. The method as set forth in claim 11, wherein the thermoplastic material is a polycarbonate material.

13. The method as set forth in claim 11, wherein the ribbon has a cross-section less than 0.01 mm².

14. The method as set forth in claim 13, wherein the encasing step includes:
building the outer envelope in layers, each layer being completed before starting a subsequent layer.

15. The method as set forth in claim 13, further including:
sanding and polishing the outer envelope.

16. The method as set forth in claim 10, wherein the encasing step includes:
placing the connected RF coil element and the electronic circuit in a mold;
filling the mold with a liquid molding material; and
molding the liquid molding material to form the seamless outer envelope.

17. The method as set forth in claim 16, further including:
prior to placing the RF coil section and the electronic circuit in the mold, mounting the RF coil section and electronic circuit in one or more pieces of plastic.

18. The method as set forth in claim 17, wherein the liquid molding material is a biologically compatible liquid urethane.

19. The method as set forth in claim 17, wherein the mold is formed of flexible silicon.

20. The coil assembly manufactured by the method of claim 10.
